(19) United States
(12) Patent Application Publication
(10) Pub. No.: US 2004/0203253 A1
(43) Pub. Date: Oct. 14, 2004

(54) Method of forming a dielectric layer

(76) Inventor: June-Min Yao, Hsinchu (TW)

Correspondence Address: BIRCH STEWART KOLASCH & BIRCH, PO BOX 747, FALLS CHURCH, VA, 22040-0747, US

(21) Appl. No.: 10/412,225

(22) Filed: Apr. 14, 2003

(51) Int. Cl. H01L 21/31

(52) U.S. Cl. 438/765

(57) ABSTRACT

A method of forming a dielectric layer on a substrate. A first in situ steam generation (ISSG) procedure is performed to form a first oxide layer on the substrate. A silicon nitride layer is formed on the first oxide layer. A second ISSG procedure is performed to form a second oxide layer on the silicon nitride layer. Moreover, during the second ISSG procedure, the silicon nitride layer can be transformed into a nitrogen-containing second oxide layer.

### BACKGROUND OF THE INVENTION

1. Field of the Invention

The present invention relates to the semiconductor manufacturing process, and more particularly, to a method of forming a dielectric layer on a substrate.

2. Description of the Related Art

The advent of micro-miniaturization, or the use of submicron features, for Integrated Circuits (ULSI, ultra large scale integration), has necessitated the use of more stable dielectric layers. Moreover, because the dielectric coefficient (k value) of silicon nitride is about 7.6, which is higher than silicon dioxide (k value is about 3.9), the industry often uses silicon nitride as a part of the dielectric layer to effectively increase k value of the dielectric layer. For example, regarding the construction of a common FLASH memory cell, an inter-gate dielectric layer between a floating gate and a control gate is an ONO (oxide/nitride/oxide) stacked structure formed by CVD, such as RTCVD or LPCVD. Also, an ONO stacked structure or a NO (nitride/oxide) stacked structure formed by CVD is often utilized in the fabrication of a capacitive dielectric layer.

However, since the multi-layer structure of the dielectric layer formed by traditional CVD is not dense, the interface structure between each layer is loose and unstable. This seriously affects the strength of interface, thereby decreasing manufacturing yield and device reliability.

### SUMMARY OF THE INVENTION

It is therefore an object of the present invention to provide a method for improving the reliability of a dielectric layer by performing at least one in situ steam generation (ISSG) procedure.

It is another object of the present invention to provide a method for increasing the interface strength of a dielectric layer having a multi-layer structure.

It is still another object of the present invention to provide a method for modulating the dielectric coefficient of a dielectric layer by performing a certain extent of ISSG procedure.

In order to accomplish the above objects, the present invention provides a method of forming a dielectric layer on a substrate. A first in situ steam generation (ISSG) procedure is performed to form a first oxide layer on the substrate. A silicon nitride layer is formed on the first oxide layer. A second ISSG procedure is performed to form a second oxide layer on the silicon nitride layer. Moreover, during the second ISSG procedure, the silicon nitride layer can be transformed into a nitrogen-containing second oxide layer.

The present invention improves on the prior art in that the fabrication of the dielectric layer includes an oxide layer formed by the ISSG procedure on a silicon nitride layer. Moreover, during the ISSG procedure, the silicon nitride layer can be transformed into a nitrogen-containing oxide layer. Thus, the invention can improve the interface strength, thereby improving reliability and yield, and ameliorating the disadvantages of the prior art. Additionally, the dielectric coefficient of a dielectric layer can be modulated via performing a certain extent of ISSG procedure.

### BRIEF DESCRIPTION OF THE DRAWINGS

The present invention can be more fully understood by reading the subsequent detailed description in conjunction with the examples and references made to the accompanying drawings, wherein:

FIGS. 1A˜1D are sectional diagrams of the first embodiment of the present invention;

FIGS. 2A˜2D are sectional diagrams of the second embodiment of the present invention;

FIGS. 3A˜3C are sectional diagrams of the third embodiment of the present invention; and

FIGS. 4A˜4C are sectional diagrams of the fourth embodiment of the present invention.

### DETAILED DESCRIPTION OF THE INVENTION

The manufacturing and use of the presently preferred embodiments are discussed below in detail. However, it should be appreciated that the present invention provides many applicable inventive concepts which can be embodied in a wide variety of specific contexts. The specific embodiments discussed are merely illustrative of specific ways to make and use the invention, and do not limit the scope of the invention.

The present invention describes a method of forming a dielectric layer having good interface reliability. Here, preferred processes for manufacturing an inter-gate dielectric layer of a FLASH memory cell are provided. It should be noted that the present method is also suitable for forming a gate insulation layer of a logic transistor, a capacitive dielectric layer of a capacitor and others.

Embodiment 1

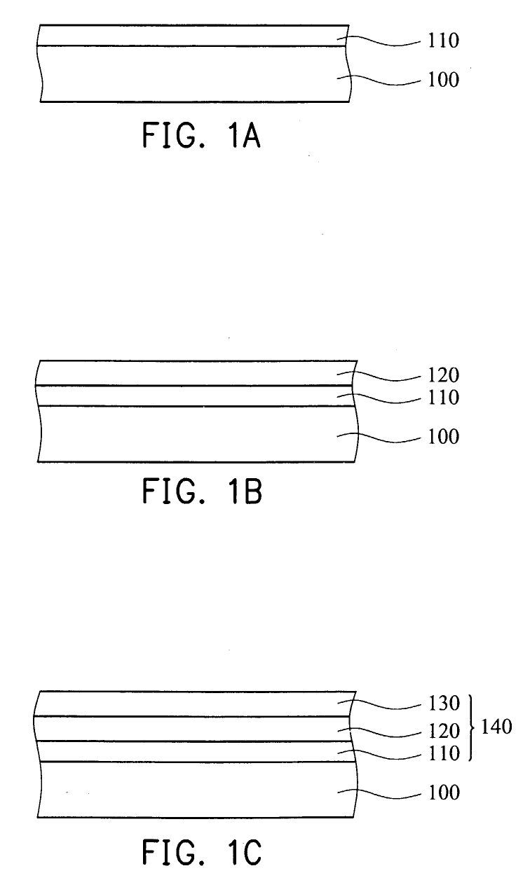

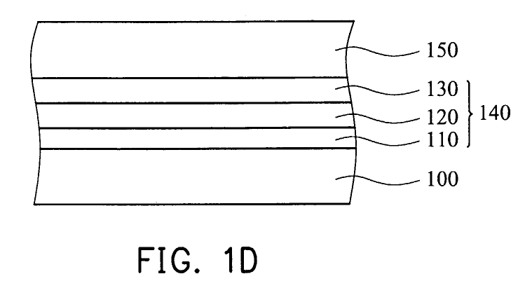

FIGS. 1A˜1D are sectional diagrams of the first embodiment of the present invention.

In FIG. 1A, a semiconductor substrate 100, such as a silicon wafer, is provided. Any desired semiconductor element, such as a polysilicon floating gate layer (not shown) of a FLASH memory cell, can be formed on the substrate 100. In order to simplify the illustration, the substrate 100 with a flat surface is shown in FIGS. 1A˜1D.

In FIG. 1A, by performing a first in situ steam generation (ISSG) procedure, the surface layer of the substrate 100 is oxidized, thus a first oxide layer 110 is formed on the substrate 100. The first oxide layer 110 may be a SiO₂ layer whose thickness is, preferably, controlled at about 20˜40 angstroms. The operation of the first ISSG procedure can be under the conditions of 800˜1000° C., 7.5˜14 torr, and in a range of hydrogen content (H₂/H₂+O₂) between 1˜33% (that is, in a range of oxygen content (O₂/H₂+O₂) between 99˜67%).

In FIG. 1B, a silicon nitride layer 120 is formed on the first oxide layer 110 by deposition, such as CVD. The gas of CVD can be NH₃ and SiH₄. In addition, the thickness of the silicon nitride layer 120 is, preferably, controlled at about 30˜170 angstroms.

In FIG. 1C, by performing a second ISSG procedure, the surface layer of the silicon nitride layer 120 is oxidized, thus a second oxide layer 130 is formed on the silicon nitride layer 120. The second oxide layer 120 may be a SiO₂ layer whose thickness is, preferably, controlled at about 20˜200 angstroms. The operation of the second ISSG procedure can be under the conditions of 800˜1000° C., 7.5˜14 torr, and in a range of hydrogen content (H₂/H₂+O₂) between 1˜33% (that is, in a range of oxygen content (0₂/H₂+O₂) between 99˜67%). Thus, a multi-layer dielectric layer 140 having the first oxide layer 110, the silicon nitride layer 120 and the second oxide layer 130 is obtained.

It should be noted that, since the second oxide layer 130 is formed by oxidizing the surface layer of the silicon nitride layer 120 via ISSG, the crystal structure of the second oxide layer 130 is denser than an oxide layer formed by traditional CVD, thereby increasing the reliability of the dielectric layer 140. Additionally, the interface strength between the silicon nitride layer 120 and the second oxide layer 130 is greater than that of the prior art.

In FIG. 1D, a conductive layer 150 serving as a control gate is further formed on the dielectric layer 140. The conductive layer 150 may be a polysilicon layer formed by CVD.

Embodiment 2

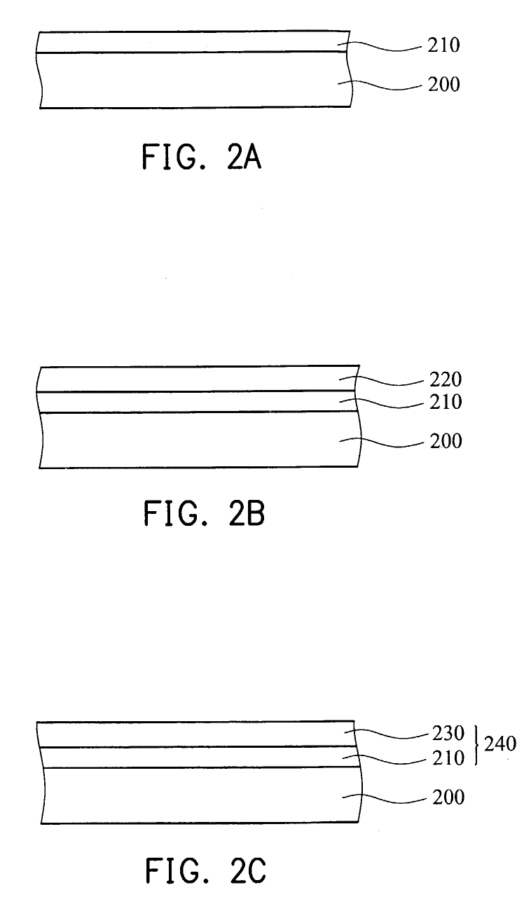

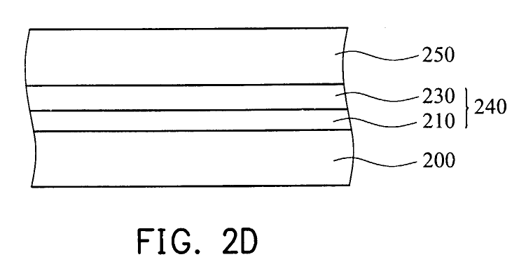

FIGS. 2A˜2D are sectional diagrams of the second embodiment of the present invention.

In FIG. 2A, a semiconductor substrate 200, such as a silicon wafer, is provided. Any desired semiconductor element, such as a polysilicon floating gate layer (not shown) of a FLASH memory cell, can be formed on the substrate 200. In order to simplify the illustration, the substrate 200 with a flat surface is shown in FIGS. 2A˜2D.

In FIG. 2A, by performing a first in situ steam generation (ISSG) procedure, the surface layer of the substrate 200 is oxidized, thus a first oxide layer 210 is formed on the substrate 200. The first oxide layer 210 may be a SiO₂ layer whose thickness is, preferably, controlled at about 20˜40 angstroms. The operation of the first ISSG procedure can be under the conditions of 800˜1000° C., 7.5-14 torr, and in a range of hydrogen content (H₂/H₂+O₂) between 1˜33% (that is, in a range of oxygen content (O₂/H₂+O₂) between 99˜67%).

In FIG. 2B, a silicon nitride layer 220 is formed on the first oxide layer 210 by deposition, such as CVD. The gas of CVD can be NH₃ and SiH₄. In addition, the thickness of the silicon nitride layer 220 is, preferably, controlled at about 30˜170 angstroms.

In FIG. 2C, a second ISSG procedure is performed to transform the silicon nitride layer 220 into a nitrogen-containing second oxide layer 230 formed on the first oxide layer 210. The nitrogen-containing second oxide layer 230 may be a SiON layer. The operation of the second ISSG procedure can be under the conditions of 800˜10000° C., 7.5˜14 torr, and in a range of hydrogen content (H₂/H₂+O₂) between 1˜33% (that is, in a range of oxygen content (0₂/H₂+O₂) between 99˜67%). Thus, a multi-layer dielectric layer 240 having the first oxide layer 210 and the nitrogen-containing second oxide layer 230 is obtained.

It should be noted that, since the nitrogen-containing second oxide layer 230 is formed by oxidizing the silicon nitride layer 220 via ISSG, the dielectric coefficient (k value) of the nitrogen-containing second oxide layer 230 is more stable than an oxide layer and a nitride layer formed by traditional CVD, thereby increasing the stability of the dielectric layer 240.

In FIG. 2D, a conductive layer 250 serving as a control gate is further formed on the dielectric layer 240. The conductive layer 250 may be a polysilicon layer formed by CVD.

Embodiment 3

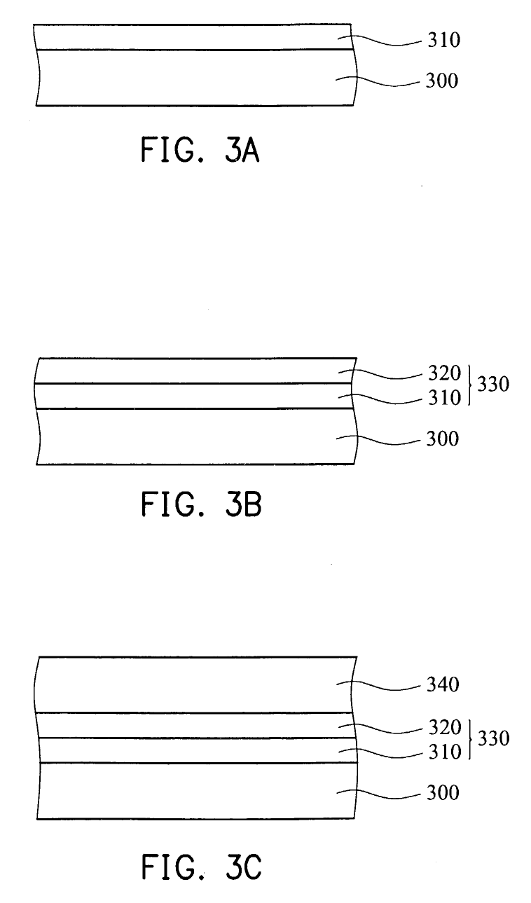

FIGS. 3A˜3C are sectional diagrams of the third embodiment of the present invention.

In FIG. 3A, a semiconductor substrate 300, such as a silicon wafer, is provided. Any desired semiconductor element, such as a polysilicon floating gate layer (not shown) of a FLASH memory cell, can be formed on the substrate 300. In order to simplify the illustration, the substrate 300 with a flat surface is shown in FIGS. 3A˜3C.

In FIG. 3A, a silicon nitride layer 310 is formed on the substrate 100 by deposition, such as CVD. The gas of CVD can be NH₃ and SiH₄. In addition, the thickness of the silicon nitride layer 120 is, preferably, controlled at about 30˜170 angstroms.

In FIG. 3B, by performing an in situ steam generation (ISSG) procedure, the surface layer of the silicon nitride layer 310 is oxidized, thus an oxide layer 320 is formed on the silicon nitride layer 310. The oxide layer 320 may be a SiO₂ layer whose thickness is, preferably, controlled at about 20˜200 angstroms. The operation of the ISSG procedure can be under the conditions of 800˜1000° C., 7.5˜14 torr, and in a range of hydrogen content (H₂/H₂+O₂) between 1˜33% (that is, in a range of oxygen content (O₂/H₂+O₂) between 99˜67%). Thus, a multi-layer dielectric layer 330 having the silicon nitride layer 310 and the oxide layer 320 is obtained.

It should be noted that, since the oxide layer 320 is formed by oxidizing the surface layer of the silicon nitride layer 310 via ISSG, the crystal structure of the oxide layer 310 is denser than an oxide layer formed by traditional CVD, thereby increasing the reliability of the dielectric layer 330. Additionally, the interface strength between the silicon nitride layer 310 and the oxide layer 320 is greater than that of the prior art.

In FIG. 3C, a conductive layer 340 serving as a control gate is further formed on the dielectric layer 330. The conductive layer 340 may be a polysilicon layer formed by CVD.

Embodiment 4

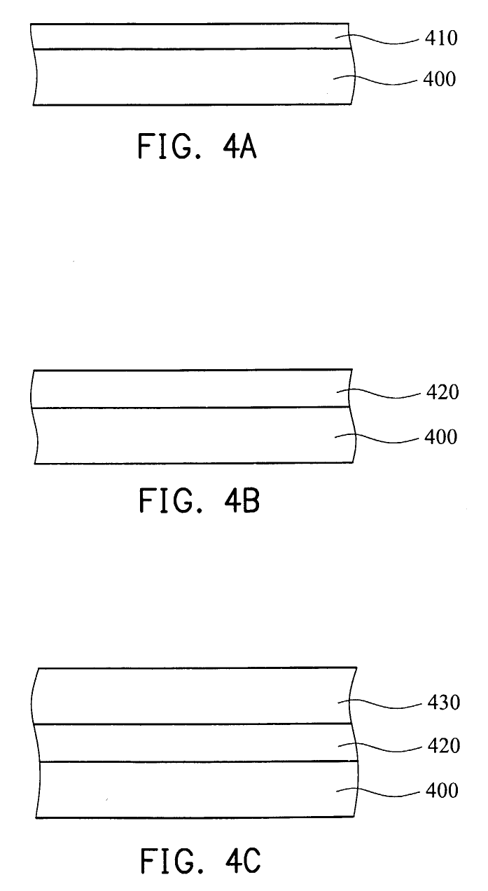

FIGS. 4A˜4C are sectional diagrams of the fourth embodiment of the present invention.

In FIG. 4A, a semiconductor substrate 400, such as a silicon wafer, is provided. Any desired semiconductor element, such as a polysilicon floating gate layer (not shown) of a FLASH memory cell, can be formed on the substrate 400. In order to simplify the illustration, the substrate 400 with a flat surface is shown in FIGS. 4A˜4C.

In FIG. 4A, a silicon nitride layer 410 is formed on the substrate 400 by deposition, such as CVD. The gas of CVD can be NH₃ and SiH₄. In addition, the thickness of the silicon nitride layer 120 is, preferably, controlled at about 30˜170 angstroms.

In FIG. 4B, an in situ steam generation (ISSG) procedure is performed to transform the silicon nitride layer 410 into a nitrogen-containing oxide layer 420 formed on the substrate 400. The nitrogen-containing oxide layer 420 may be a SiON layer. The operation of the ISSG procedure can be under the conditions of 800˜1000° C., 7.5˜14 torr, and in a range of hydrogen content (H₂/H₂+O₂) between 1˜33% (that is, in a range of oxygen content (O₂/H₂+O₂) between 99˜67%). Thus, a dielectric layer 420 is obtained.

It should be noted that, since the nitrogen-containing oxide layer 420 is formed by oxidizing the silicon nitride layer 410 via ISSG, the dielectric coefficient (k value) of the nitrogen-containing oxide layer 420 is more stable than an oxide layer and a nitride layer formed by traditional CVD, thereby increasing the stability of the dielectric layer 420.

In FIG. 4C, a conductive layer 430 serving as a control gate is further formed on the dielectric layer 420. The conductive layer 430 may be a polysilicon layer formed by CVD.

Therefore, the present invention provides a method of forming a dielectric layer formed on a substrate. The present method uses the ISSG procedure to form an oxide layer formed on a silicon nitride layer. Moreover, during the ISSG procedure, the silicon nitride layer can be transformed into a nitrogen-containing oxide layer. Thus, the invention improves the interface strength, thereby improving reliability and yield, and ameliorating the disadvantages of the prior art. Additionally, the dielectric coefficient of a dielectric layer can be modulated via performing a certain extent of ISSG procedure.

Finally, while the invention has been described by way of example and in terms of the above, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming a dielectric layer on a substrate, comprising the steps of:
performing a first in situ steam generation (ISSG) procedure to form a first oxide layer on the substrate;
forming a silicon nitride layer on the first oxide layer; and
performing a second ISSG procedure to form a second oxide layer on the silicon nitride layer;
wherein the dielectric layer is composed of the first oxide layer, the silicon nitride layer and the second oxide layer.

2. The method according to claim 1, wherein the substrate is a silicon substrate.

3. The method according to claim 2, wherein the first oxide layer is a SiO₂ layer.

4. The method according to claim 1, wherein the first ISSG procedure is performed at a temperature between 800 to 1000° C., in a range of hydrogen content (H2/H2+O2) between 1˜33%, and at a pressure between 7.5˜14 torr.

5. The method according to claim 1, wherein the silicon nitride layer is formed by deposition.

6. The method according to claim 5, wherein the deposition is CVD.

7. The method according to claim 1, wherein the second ISSG procedure is performed at a temperature between 800 to 1000° C., in a range of hydrogen content (H₂/H₂+O₂) between 1˜33%, and at a pressure between 7.5˜14 torr.

8. A method of forming a dielectric layer on a substrate, comprising the steps of:
performing a first in situ steam generation (ISSG) procedure to form a first oxide layer on the substrate;
forming a silicon nitride layer on the first oxide layer; and
performing a second ISSG procedure to transform the silicon nitride layer into a nitrogen-containing second oxide layer formed on the first oxide layer;
wherein the dielectric layer is composed of the first oxide layer and the nitrogen-containing second oxide layer.

9. The method according to claim 8, wherein the substrate is a silicon substrate.

10. The method according to claim 9, wherein the first oxide layer is a SiO₂ layer.

11. The method according to claim 8, wherein the first ISSG procedure is performed at a temperature between 800 to 1000° C., in a range of hydrogen content (H2/H2+02) between 1˜33%, and at a pressure between 7.5˜14 torr.

12. The method according to claim 8, wherein the silicon nitride layer is formed by deposition.

13. The method according to claim 12, wherein the deposition is CVD.

14. The method according to claim 8, wherein the second ISSG procedure is performed at a temperature between 800 to 1000° C., in a range of hydrogen content (H₂/H₂+O₂) between 1˜33%, and at a pressure between 7.5-14 torr.

15. A method of forming a dielectric layer on a substrate, comprising the steps of:
forming a silicon nitride layer on the substrate; and
performing an in situ steam generation (ISSG) procedure to form a oxide layer on the silicon nitride layer;
wherein the dielectric layer is composed of the silicon nitride layer and the oxide layer.

16. The method according to claim 15, wherein the silicon nitride layer is formed by deposition.

17. The method according to claim 15, wherein the ISSG procedure is performed at a temperature between 800 to 1000° C., in a range of hydrogen content (H₂/H₂+O₂) between 1˜33%, and at a pressure between 7.5˜14 torr.

18. A method of forming a dielectric layer on a substrate, comprising the steps of:
forming a silicon nitride layer on the substrate; and
performing an in situ steam generation (ISSG) procedure to transform the silicon nitride layer into a nitrogen-containing oxide layer formed on the substrate.

19. The method according to claim 18, wherein the silicon nitride layer is formed by deposition.

20. The method according to claim 18, wherein the ISSG procedure is performed at a temperature between 800 to 1000° C., in a range of hydrogen content (H₂/H₂+O₂) between 1˜33%, and at a pressure between 7.5˜14 torr.
